(19) United States
(12) Patent Application Publication
(10) Pub. No.: US 2019/0277931 A1
(43) Pub. Date: Sep. 12, 2019

(54) METHOD AND APPARATUS FOR RECORDING MAGNETIC RESONANCE DATA FOR QUANTITATIVE MAGNETIC RESONANCE IMAGING

(71) Applicant: Siemens Healthcare GmbH, Erlangen (DE)

(72) Inventors: Dominik Paul, Bubenreuth (DE); Flavio Carinci, Erlangen (DE); Mario Zeller, Erlangen (DE)

(73) Assignee: Siemens Healthcare GmbH, Erlangen (DE)

(21) Appl. No.: 16/296,712

(22) Filed: Mar. 8, 2019

(30) Foreign Application Priority Data
Mar. 8, 2018 (EP) 18160710

(51) Int. Cl. G01R 33/54; G01R 33/50; G01R 33/561; G01R 33/483

(52) U.S. Cl. CPC G01R 33/546; G01R 33/4835; G01R 33/5615; G01R 33/50

(57) ABSTRACT

In a method and apparatus for recording magnetic resonance data for determining at least one parameter map describing a material parameter in the scanning region, the scanning area having a number of slices, a slice-specific preparation pulse is used, wherein magnetic resonance data are scanned after different waiting times following the preparation pulse. Magnetic resonance data of different waiting times are acquired from at least two slices, by determining an overall pulse by overlaying the slice-specific preparation pulses for the individual slices, and then activating the overall pulse to read out the magnetic resonance data of the slices with a readout sequence after the respective waiting times.

### BACKGROUND OF THE INVENTION

### Field of the Invention

The invention concerns a method for recording magnetic resonance data for determining at least one parameter map describing a material parameter in the scanning region with a magnetic resonance apparatus, of the type wherein the scanning area has a number of slices and, for recording the magnetic resonance data, a slice-specific preparation pulse is used at least partially, wherein magnetic resonance data are scanned after different waiting times following the preparation pulse. The invention also concerns a magnetic resonance apparatus and an electronically readable data carrier for implementing such a method.

### Description of the Prior Art

Magnetic resonance imaging is now well-established in clinical use. Apart from the classical recording of magnetic resonance images, quantitative magnetic resonance imaging is increasingly gaining in importance. In quantitative magnetic resonance imaging, magnetic resonance data are recorded with different recording parameters from the same slices of the scanning region in order to derive material parameters computationally, which can then be represented in the form of a parameter map. The material parameters can be, for example, the T1-relaxation time, the T2-relaxation time, the T2*-relaxation time, the proton density and the magnetic susceptibility. The accuracy of such parameter maps depends ultimately on the number of measurement points, which means in how many different ways magnetic resonance data have been recorded from particular points in the space, wherein usually different contrast parameters are used as recording parameters.

With regard to clinical use, as a result of the multiple recording of magnetic resonance data from the individual slices, in particular when parameter maps are to be determined for a number of material parameters, there result very long scan times that are not consistent with the short examination times that are desirable in current practice.

In order to obtain different magnetic resonance data from the slices, from which material parameters can be determined, it has been proposed to record magnetic resonance data at different waiting times after the emission of a preparation pulse, wherein an inversion pulse is used as the preparation pulse, and therefore different inversion times TI are observed. For this purpose, the T1-relaxation time is determined as a material parameter. Following inversion preparations, however, long repetition times TR are needed in order to relax as much magnetic resonance signal as possible, which leads to very long recording times. If, for example, the recording of the magnetic resonance data is based upon a spin echo sequence, such as a turbo spin echo sequence (TSE sequence), then a recording of the same slice for a second inversion time cannot take place immediately after a first data recording at a first inversion time, since no magnetic resonance signal is present any longer. Therefore, the two recordings of the magnetic resonance data are carried out separately. A number of concatenations are often necessary in this context in order to assemble a complete dataset. A long recording time results.

DE 10 2012 206 585 A1 describes a method for rapid spatially resolved determination of a magnetic resonance relaxation parameter in an examination region. It is proposed therein that after a preparation pulse for one slice during the relaxation of the longitudinal magnetization at least at two different inversion times, to acquire spatially encoded magnetic resonance signals using a rapid magnetic resonance sequence, in order to reconstruct an image data set at each inversion time. The reconstructed image data sets are elastically registered to one another and the relaxation parameter is determined from the registered image data sets at the correct position.

For scan time reduction in quantitative magnetic resonance imaging with a data recording after preparation pulses, it has also been proposed to use imaging techniques such as parallel imaging (PAT—parallel acquisition technique) and compressed sensing (CS). However, the overall recording time is still very long, so that a further acceleration is desirable.

### SUMMARY OF THE INVENTION

An object of the invention is to achieve acceleration of the scan in quantitative magnetic resonance imaging with slice-selective preparations.

In order to achieve this object in a method of the type mentioned in the introduction for recording magnetic resonance data after different waiting times from at least two slices, in accordance with the invention an overall pulse is determined by overlaying the slice-specific preparation pulses for the individual slices, and is activated during the MR data acquisition so the magnetic resonance data of the slices are read out with a readout sequence after the respective waiting times.

According to the invention, therefore, a nesting of the recording of magnetic resonance data from different slices takes place, with simultaneous use of preparation pulses according to the multislice imaging method (SMS—simultaneous multislice). In order to achieve this, an overall pulse is used that has been determined comparably with SMS imaging by overlaying slice-specific preparation pulses, and therefore acts simultaneously on two or more slices. This means, in contrast to the known procedure, that two or more slices are acquired simultaneously. The magnetic resonance data of the at least two prepared slices can be read out at two different time points, namely at different waiting times. Thus the recording processes can be nested within one another and therefore a significant time gain is achieved, in particular by a factor of 2 or more.

The present invention is based on the insight that, although it may not be reasonably possible to record MR data, following a single preparation pulse, within the same slice, for example using a TSE sequence at two different waiting times, in particular inversion times, the problems associated therewith are circumvented when two different slices are selected that are both prepared according to the SMS imaging so that their slice-specific preparation pulses are brought together to form a common overall pulse, which is then activated. The readout echo trains according to this readout sequence are offset relative to one another such that for one slice, the first waiting time, and for the other slice, the second waiting time, are covered.

It is particularly suitable in this regard if, in a second repetition, the slices are swapped, which means that the second slice is then read out after the first waiting time and the first slice is read out after the second waiting time, so that finally, magnetic resonance data are present at all waiting times from all the slices. This can naturally be used accordingly for the simultaneous preparation of more than two slices.

A spin echo sequence, in particular a turbo spin echo (TSE) sequence, can be used as the readout sequence. At least one inversion pulse and/or a saturation pulse can be used as the slice-specific preparation pulse. This means that the method can also be used, in particular, with different slice-selective preparations.

In an embodiment of the present invention, slice-specific preparation pulses of different flip angles are overlaid to form the overall pulse. This means that the flip angle of the slice-specific preparation pulse can be set differently for the at least two slices to be prepared simultaneously. This provides the possibility to record different contrasts, for example, an IR (inversion recovery) contrast and an SR (saturation recovery) contrast. Thus an additional degree of freedom, which further enhances the quality and accuracy of the parameter maps, is utilized. In addition, the possibility of the variation of the flip angle offers an option for reducing the specific absorption rate (SAR) for the patient, so that advantages can be gained in this regard as well.

In an embodiment of the invention, at least three slices are scanned wherein, for at least two slices on which the overall pulse acts, the magnetic resonance data of a common waiting time are read out simultaneously and separated by a separation algorithm. This means that the simultaneous preparation of a number of slices, for which readout at different waiting times takes place, can be combined with conventional SMS imaging techniques. For example, with the overall pulse, four slices can be prepared simultaneously and in each case 2×2 slices can be read out simultaneously. In this way, a further acceleration of the recording of the magnetic resonance data can be achieved.

The present invention also concerns a magnetic resonance apparatus having a control computer configured to implement the method according to the invention. The control computer hereby has at least one processor and at least one memory. All the embodiments relating to the method according to the invention apply to the inventive magnetic resonance apparatus, so that the aforementioned advantages can also be achieved therewith. Such a control computer can include a sequence controller of a known type, which controls the recording of magnetic resonance data. In accordance with the present invention, the control computer includes an overall pulse determining processor or planning processor for determining the overall pulse by overlaying the slice-specific preparation pulses and/or for planning the time sequence.

The present invention also encompasses a non-transitory, computer-readable data storage medium encoded with programming instructions that, when the storage medium is loaded into a computer or computer system of an magnetic resonance apparatus, cause the computer or computer system to operate the magnetic resonance apparatus so as to implement any or all embodiments of the method according to the invention, as described above.

### BRIEF DESCRIPTION OF THE DRAWINGS

FIG. 1 illustrates the time sequence of data recording from jointly prepared slices in a first exemplary embodiment of the invention.

FIG. 2 illustrates the time sequence during the data recording from jointly prepared slices in a second exemplary embodiment of the invention.

FIG. 3 schematically illustrates an inventive magnetic resonance apparatus.

### DESCRIPTION OF THE PREFERRED EMBODIMENTS

In the following exemplary embodiments, quantitative magnetic resonance imaging, in particular at least in relation to the T1-relaxation time as a material parameter, is to be applied in a scanning region of a patient that is divided into a plurality of slices. An inversion pulse is to be used as the preparation pulse, wherein after different waiting times, that is, inversion times, magnetic resonance data is to be recorded from the corresponding slices.

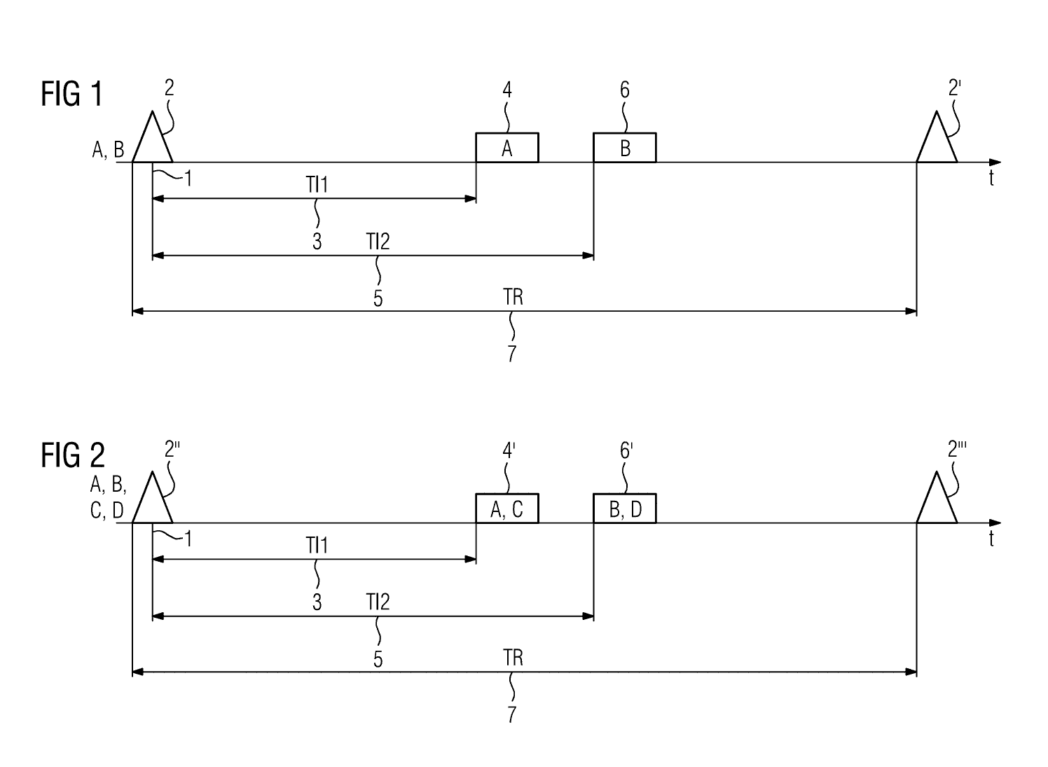

In a first actual exemplary embodiment shown in detail in FIG. 1, in the scanning of two different waiting times TI1 and TI2, all the slices are to be divided into pairs of two slices A, B each. The division takes place thereby in the SMS imaging so that as little slice crosstalk as possible occurs during the influencing of the slices within a joint repetition.

For the recording of the magnetic resonance data, initially an overall pulse is determined according to methods of SMS imaging from two slice-specific preparation pulses by overlaying.

During the actual recording process, therefore, at a time point 1 through output of the overall pulse 2 (only indicated here), a preparation of both slices A, B is achieved. After a first waiting time 3, in a readout echo train 4 which in the present case uses a TSE sequence as the readout sequence, a recording of magnetic resonance data from the first slice can take place. After a waiting time 5, the recording of magnetic resonance data from the second slice B takes place in a further readout echo train 6, again making use of a TSE sequence.

After the repetition time TR, the next overall pulse 2′ for the next pair of slices A′, B′ is output. At a later time point in a further repetition, in addition, an inverted scanning of the slices A, B (and the further pairs) takes place, which means that magnetic resonance data of slice B is recorded after the first waiting time 3 and magnetic resonance data of slice A is recorded after the second waiting time 5. The repetition time is additionally identified in FIG. 1 with the reference sign 7.

Once magnetic resonance data have been recorded for all the pairs and all the waiting times 3, 5 (and possibly further pairs of waiting times), these can be further processed accordingly, in particular by reconstruction of magnetic resonance images at the corresponding contrasts and processing thereof in order to determine parameter maps, in particular at least with regard to the T1-relaxation time.

It should also be noted that it is possible (and preferred) to use different flip angles for the preparation pulses that are to be overlaid, since then not only can SAR be saved, but also further different contrasts can be scanned.

FIG. 2 shows a combination of the procedure of FIG. 1 with the conventional magnetic resonance imaging. The overall pulse 2″ shown there does not act here on slices A and B, but on slices C and D. From the slice C, also following the first waiting time 3, magnetic resonance data are to be scanned, as well as from the slice D after the second waiting time 5. Accordingly, in the readout echo trains 4′, 6′, overlaid magnetic resonance data of the slices A, C or B, D is respectively recorded and can then be separated again. A known separation algorithm, for example, a slice GRAPPA algorithm, can be used in order to produce, as in the first exemplary embodiment of FIG. 1, magnetic resonance images for the different contrasts/waiting times 3, 5 and to calculate the at least one parameter map therefrom. In concrete terms, for example, for determining the T1-relaxation time from scans at different inversion times, reference is made to DE 10 2012 206 585 A1 cited in the introduction.

By the simultaneous preparation (and according to FIG. 2, simultaneous scanning) of a number of slices, a significant reduction of the overall recording time for the magnetic resonance data for determining the at least one parameter map can be achieved.

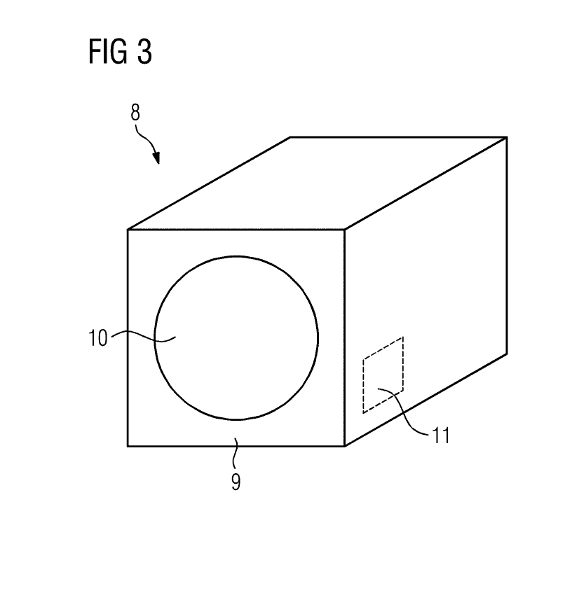

FIG. 3 shows the basic components of an inventive magnetic resonance apparatus 8. It has a scanner with a basic field magnet that defines a patient receiving space 10, into which a patient can be moved by a patient support (not shown) for recording magnetic resonance data. A radio-frequency coil arrangement and a gradient coil arrangement (not shown) surround the patient receiving space 10 in a known manner.

The operation of the magnetic resonance apparatus 8 is controlled by a control computer 11 that is configured for carrying out the inventive method. For this purpose, apart from a sequence controller for controlling the recording of magnetic resonance data, the control system 11 has an overall pulse determining processor or generally a planning processor in order to determine suitable pulses 2, 2′, 2″, 2′″ and to plan the time sequence of the recording of magnetic resonance data, for example, according to FIG. 1 or 2.

Although modifications and changes may be suggested by those skilled in the art, it is the intention of the Applicant to embody within the patent warranted hereon all changes and modifications as reasonably and properly come within the scope of the Applicant's contribution to the art.

1. A method for operating a magnetic resonance (MR) apparatus comprising:
acquiring MR data from a plurality of different slices of an examination region of a subject by operating an MR apparatus so as to radiate a slice-specific preparation pulse and acquiring MR data respectively from the different slices after respectively different waiting times following radiation of the slice-specific preparation pulse;
in a computer, determining an overall pulse for acquiring said MR data at said different waiting times by overlaying respective slice-specific preparation pulses for the individual slices and, from said computer, operating said MR apparatus by activating said overall pulse and reading out said MR data from the respective slices with a readout sequence after the respective waiting times; and
from the MR data that are read out from the respective slices, determining, in said computer, at least one parameter map that describes a material parameter in said examination region.

2. A method as claimed in claim 1 comprising operating said MR apparatus with a sequence, as said readout sequence, selected from the group consisting of a spin echo sequence and a turbo spin echo sequence.

3. A method as claimed in claim 1 comprising radiating each slice-specific preparation pulse as a pulse selected from the group consisting of inversion pulses and saturation pulses.

4. A method as claimed in claim 1 comprising operating said MR apparatus with a sequence, as said readout sequence, selected from the group consisting of a spin echo sequence and turbo spin echo sequence, and radiation each slice-specific preparation pulse as a pulse selected from the group consisting of inversion pulses and saturation pulses.

5. A method as claimed in claim 1 comprising, in said computer, determining said overall pulse by overlaying respective slice-specific preparation pulses with different flip angles.

6. A method as claimed in claim 1 comprising operating said MR apparatus to acquire MR data from at least three slices in said examination region, with said overall pulse acting on at least two of said three slices, and reading out said MR data simultaneously from said at least two slices after a same waiting time, and separating the MR data simultaneously read out from said at least two slices by executing a separation algorithm in said computer.

7. A magnetic resonance (MR) apparatus comprising:
an MR data acquisition scanner;
a computer configured to operate sad MR data acquisition scanner so as to acquire MR data from a plurality of different slices of an examination region of a subject, by radiating a slice-specific preparation pulse and acquiring MR data respectively from the different slices after respectively different waiting times following radiation of the slice-specific preparation pulse;
said computer being configured to determine an overall pulse for acquiring said MR data at said different waiting times by overlaying respective slice-specific preparation pulses for the individual slices, and to operate said MR apparatus by activating said overall pulse and reading out said MR data from the respective slices with a readout sequence after the respective waiting times; and
said computer being configured to determine, from the MR data that are read out from the respective slices, at least one parameter map that describes a material parameter in said examination region.

8. A non-transitory, computer-readable data storage medium encoded with programming instructions, said storage medium being loaded into a computer of a magnetic resonance (MR) apparatus, and said programming instructions causing said computer to:
acquire MR data from a plurality of different slices of an examination region of a subject by operating said MR apparatus so as to radiate a slice-specific preparation pulse and acquiring MR data respectively from the different slices after respectively different waiting times following radiation of the slice-specific preparation pulse;
determine an overall pulse for acquiring said MR data at said different waiting times by overlaying respective slice-specific preparation pulses for the individual slices, and operate said MR apparatus by activating said overall pulse and reading out said MR data from the respective slices with a readout sequence after the respective waiting times; and
from the MR data that are read out from the respective slices, determine at least one parameter map that describes a material parameter in said examination region.
